(19) United States
(12) Patent Application Publication
(10) Pub. No.: US 2017/0213765 A1
(43) Pub. Date: Jul. 27, 2017

(54) DIE BONDING/DICING SHEET

(71) Applicant: HITACHI CHEMICAL COMPANY, LTD., Tokyo (JP)

(72) Inventors: Ryouji FURUTANI, Chiba-shi, Chiba (JP); Kouji SUZUMURA, Ichihara-shi, Chiba (JP); Yukihiro IWANAGA, Chiba-shi, Chiba (JP); Yuuki NAKAMURA, Ichihara-shi, Chiba (JP)

(21) Appl. No.: 15/313,331

(22) PCT Filed: May 19, 2015
(86) PCT No.: PCT/JP2015/064302

§ 371 Date: Nov. 22, 2016

(30) Foreign Application Priority Data
May 23, 2014 (JP) 2014-107251

(51) Int. Cl. H01L 21/78; B23K 26/53; H01L 21/683; B23K 26/00

(52) U.S. Cl. CPC H01L 21/78; B23K 26/0006; B23K 26/0057; B23K 26/53; H01L 21/6836; B23K 2201/40

(57) ABSTRACT

A die bonding/dicing sheet, which can solve the problems of the peeling and the dispersion of an adhesive layer from a pressure sensitive adhesive layer in expanding and further the adhesion thereof to a semiconductor chip, is provided. The die bonding/dicing sheet, which is attached to a support member for mounting a semiconductor element in use, comprising: a peerable first base material; an adhesive layer provided on one surface of the first base material; a pressure sensitive adhesive layer, which covers a whole upper surface of the adhesive layer and has a peripheral part which does not overlap the adhesive layer; and a second base material provided on an upper surface of the pressure sensitive adhesive layer, wherein a plane outer shape of the adhesive layer is larger than a plane outer shape of the support member for mounting the semiconductor element, and a distance between an edge of the adhesive layer and an edge of the support member is 1 mm or more and 12 mm or less.

### TECHNICAL FIELD

The present invention relates to a die bonding/dicing sheet, which can suitably be used in producing of a semiconductor device.

### BACKGROUND ART

Conventionally, silver paste has mainly been used for bonding of a semiconductor chip and a support member such as a lead frame. However, in recent years, along with miniaturization of semiconductor chips and its high-performance, there are requirements for miniaturization and densification concerning a lead frame used together with the chips. In spite of the above-mentioned requirements, when the silver paste is used for the above-mentioned bonding, defects tend to easily occur at the time of wire bonding due to the oozing of the paste or the inclination of a semiconductor chip. Besides, for example, it is difficult to control the thickness of an adhesive layer, and voids easily occur in the adhesive layer. Therefore, there have been limitations to deal with the above-mentioned requirements by using the silver paste.

Therefore, a bonding method using adhesive film members such as a film-like adhesive agent and a film-like die bonding material, which would performed by “the cut and lamination method” or “the wafer backside lamination method”, has been used in recent years, in place of the silver paste.

When a semiconductor device is produced by the above-mentioned cut and lamination method, atypical production process comprises the following (1) to (3).
(1) By cutting or punching of a roll (reel)-like adhesive film, an individual piece of the adhesive film is provided. The above-mentioned individual piece is then attached to a lead frame.
(2) A small piece of an element (semiconductor chip) formed by cut and separated (dicing) in previous dicing step is set on the obtained lead frame with the adhesive film. These are then bonded (die bonding), whereby a lead frame with the semiconductor chip is produced.
(3) The wire bonding step and the sealing step are performed.

In such method, however, a dedicated assembling device is required to cut out an individual piece of the adhesive film from the roll-like adhesive film and further attach the cut individual piece of the adhesive film to a lead frame. Therefore, since the production cost is higher than that of the method using silver paste, improvement is demanded.

In the meantime, when a semiconductor device is produced by the above-mentioned wafer backside lamination method, a typical production process comprises the following (1) to (4).
(1) An adhesive film is attached to the backside of a semiconductor wafer, and further a dicing tape is laminated on the adhesive film.
(2) The dicing step is performed by dicing the semiconductor wafer together with the adhesive film, whereby obtaining individual pieces thereof.
(3) Each individual piece of the obtained semiconductor chips with the adhesive film is picked up and is attached to a lead frame.
(4) For example, a step for curing the adhesive film by heating, the wire bonding step and the sealing step for example are then performed.

In such method, the adhesive film and the semiconductor wafer are diced together to produce a semiconductor chip with the adhesive film, and thus a device for independently dicing the adhesive film is not required. Therefore, an assembling device used in the method using conventional silver paste can be used without modification. Alternatively, the above-mentioned device can be used by adding partly improvement, for example by adding a heating platen to the assembling device. Thus production cost can be kept relatively cheap in the above-mentioned method. However, this method requires two attaching steps, that is attaching an adhesive film and then attaching a dicing tape, prior to the dicing step.

Therefore, the development of an adhesive film member which does not require the two attaching steps but requires only one attaching step has been proceeding. As an example of such film member, a “die bonding/dicing sheet” which is formed by laminating an adhesive film and a dicing tape in advance, or a sheet which can be used for both the dicing step and the die bonding step or the like is known.

An example thereof includes a die bonding/dicing sheet having a four-layer structure of base material/pressure sensitive adhesive layer/adhesive layer/peelable sheet (e.g. Patent Literature 1). In Patent Literature 1, as shown in FIGS. 1(a) and 1(b), a disk-shaped adhesive layer (die bonding material) 12 is formed on a peelable sheet 10, a disk-shaped pressure sensitive adhesive layer 13 with a size larger than the above-mentioned adhesive layer 12 is laminated thereon, and a base material 14 with a size and shape equal to those of the pressure sensitive adhesive layer 13 is further laminated thereon, thereby producing the above-mentioned sheet. Patent Literature 1 also discloses that the above-mentioned pressure sensitive adhesive layer 13 is constituted of a radioactive ray-curable pressure sensitive adhesive, and elastic modulus after curing by radioactive rays is maintained in the predetermined range, and thus expanding properties and pick-up properties after the dicing step would be good. Besides, a die bonding/dicing sheet having a three-layer structure of base material/adhesive layer/peelable sheet is also known.

Conventionally, in the dicing step, a dicing of a wafer has been performed by using a cutting knife called a blade. However, a stealth dicing method for dicing a wafer by stretching a dicing tape has been applied in recent years, along with requirements of thin wafer and downsized chip. The above-mentioned stealth dicing method has typically the following steps as shown in FIG. 2. The example shown by FIGS. 2(a) to 2(d) are corresponding to a case using the above-described die bonding/dicing sheet having a three-layer structure.
(1) By irradiating a common semiconductor wafer 30 with a laser, a modified part 30a is formed in the inside of the wafer (FIG. 2(a)),
(2) a peelable sheet 10 of the die bonding/dicing sheet is peeled off to expose an adhesive layer 12 (FIG. 2(b)),
(3) the wafer 30 having the modified part 30a and a dicing ring 40 are laminated on the above-mentioned exposed surface of the adhesive layer 12 (FIG. 2(c)), and
(4) a base material 14 and a pressure sensitive adhesive layer 13 (dicing tape) are stretched using an expanding jig 50 to cut the wafer by expanding, and chips which are individual pieces are provided (FIG. 2(d)).

### CITATION LIST

### Patent Literature

Patent Literature 1: JP 7-045557 A

### SUMMARY OF INVENTION

### Problems to be Solved by the Invention

When a die bonding/dicing sheet of a four-layer structure (see FIGS. 1(a) and 1(b)) is applied in the dicing step by the above-mentioned stealth dicing method, a semiconductor device can be typically produced by the following steps as shown in FIGS. 3(a) to 3(d).
(1) A peelable sheet 10 of the die bonding/dicing sheet is peeled off to expose a part of an adhesive layer 12 and a pressure sensitive adhesive layer 13 (FIG. 3(a)). The above-mentioned exposed part of the pressure sensitive adhesive layer 13 has a strip-like circle shape and is a region to put a dicing ring.
(2) A dicing ring 40 is then put on the above-mentioned exposed part of the pressure sensitive adhesive layer 13, and a semiconductor wafer 30 having a modified part 30a previously formed therein with a laser is put on the predetermined place (on the adhesive layer 12) in the inside of the ring (FIGS. 3(b) and 3(c)).
(3) A base material 14 and the pressure sensitive adhesive layer 13 (dicing tape) are then stretched using an expanding jig 50 to cut the semiconductor wafer 30 and the adhesive layer 12 simultaneously, thereby producing a semiconductor chip with the adhesive layer (12b and 30b) (FIG. 3(d)).
(4) The above-mentioned semiconductor chip with the adhesive layer is picked up from the surface of the pressure sensitive adhesive layer 13 and put on a lead frame, and subjected to heating and bonding (die bonding). Subsequently, a wire bonding treatment is performed and the semiconductor chip is sealed with a sealing material (not shown).

In the above-described production method, however, when a semiconductor wafer attached to the film-like adhesive layer (see FIGS. 3(c) and (d)) is cut by expanding to dice the adhesive layer and the wafer simultaneously, a defect in which a part of the adhesive layer is peeled off and adheres to the upper surface of the semiconductor wafer may occur. This is called the dispersion of DAF (Die Attach Film). More specifically, as shown in FIGS. 4(a) and 4(b), the dispersion of DAF is a phenomenon of the following: a part of an adhesive layer 12c (FIG. 4(a)), which is located outside a semiconductor wafer 30 and is out of contact with the semiconductor wafer, is peeled off and dispersed from a pressure sensitive adhesive layer 13 due to an impact at the time of cutting by expanding; and then adheres to the upper surface of a semiconductor chip 30b obtained after the cutting of the semiconductor wafer (FIG. 4(b)). In FIG. 4(b), the reference numeral 12c′ shows the adhesive layer which is dispersed and adheres to the upper surface of the chip. As described above, the chip to which a dispersed adhesive layer adheres cannot be picked up, which decreases productivity, and thus improvements are demanded.

In view of such circumstances, an object of the present invention is to provide a die bonding/dicing sheet, which can solve the problems of the peeling of an adhesive layer from a pressure sensitive adhesive layer at the time of expanding, and the dispersion of the adhesive layer, and further the adhesion thereof to a semiconductor chip.

### Means to Solve the Problems

As a result of various investigations to achieve the above-mentioned object, the present inventors found that the dispersion of an adhesive layer at the time of cutting by expanding could be prevented by setting the size of the adhesive layer to a size which is equal to that of a semiconductor wafer, or setting the size of the adhesive layer to a size which is close to that of the semiconductor wafer, thereby the present invention was completed. The present invention relates to the following matters.

(1) A die bonding/dicing sheet, which is attached to a support member for mounting a semiconductor element in use, comprising: a first base material which is peelable; an adhesive layer provided on one surface of the first base material; a pressure sensitive adhesive layer, which covers a whole upper surface of the adhesive layer and has a peripheral part which does not overlap the adhesive layer; and a second base material provided on an upper surface of the pressure sensitive adhesive layer, wherein a plane outer shape of the adhesive layer is larger than a plane outer shape of the support member for mounting the semiconductor element, and a distance between an edge of the adhesive layer and an edge of the support member is 1 mm or more and 12 mm or less.

(2) The die bonding/dicing sheet according to the above-mentioned (1), wherein the support member for mounting the semiconductor element is a semiconductor wafer.

(3) The die bonding/dicing sheet according to the above-mentioned (1) or (2), wherein the first base material is long in shape, and a plurality of laminates comprising the adhesive layer, the pressure sensitive adhesive layer and the second base material is arranged in an island-like form on an upper surface of the long-shaped first base material, and a side of the upper surface of the long-shaped first base material is wound inward in long direction into a roll-like form.

(4) The die bonding/dicing sheet according to any one of the above-mentioned (1) to (3), wherein the second base material is a dicing sheet base material which is not broken when cut by expanding is performed in accordance with a stealth dicing method.

(5) A method for producing a semiconductor device, comprising a cutting process by expanding performed in accordance with a stealth dicing method, wherein the cutting process comprises: (i) forming a modified part by irradiating a support member for mounting a semiconductor element with a laser; (ii) laminating the support member for mounting the semiconductor element, and a die bonding/dicing sheet having in turn a peelable first base material, an adhesive layer, a pressure sensitive adhesive layer and a second base material, wherein the adhesion layer is exposed by peeling off the first base material of the die bonding/dicing sheet, and subsequently the adhesive layer and the support member for mounting the semiconductor element are laminated; and then (iii) expanding the second base material and the pressure sensitive adhesive layer of the die bonding/dicing sheet to simultaneously cut the support member for mounting the semiconductor element and the adhesive layer, whereby obtaining individual pieces of the support member for mounting the semiconductor element with the adhesive layer, and wherein as the die bonding/dicing sheet in the cutting process, the die bonding/dicing sheet according to any one of the above-mentioned (1) to (4) is used.

(6) The method for producing a semiconductor device according to the above-mentioned (5), wherein the step (iii) is performed under a condition of the expanding that the second base material and the pressure sensitive adhesive layer are not cut.

The disclosure of the present application relates to the subject matter described in Japanese Patent Application No. 2014-107251, filed on May 23, 2014, the disclosed contents of which are incorporated herein for reference.

### Advantageous Effects of Invention

According to the present invention, the problems such as the peeling and dispersion of an adhesive layer from a pressure sensitive adhesive layer at the time of expanding and further the adhesion of the adhesive layer to a semiconductor chip, can be solved.

### BRIEF DESCRIPTION OF DRAWINGS

FIGS. 1(a) and 1(b) are views showing the structure of a die bonding/dicing sheet, and (a) is a plan view and (b) is a cross-sectional view taken along the line A-A in (a).

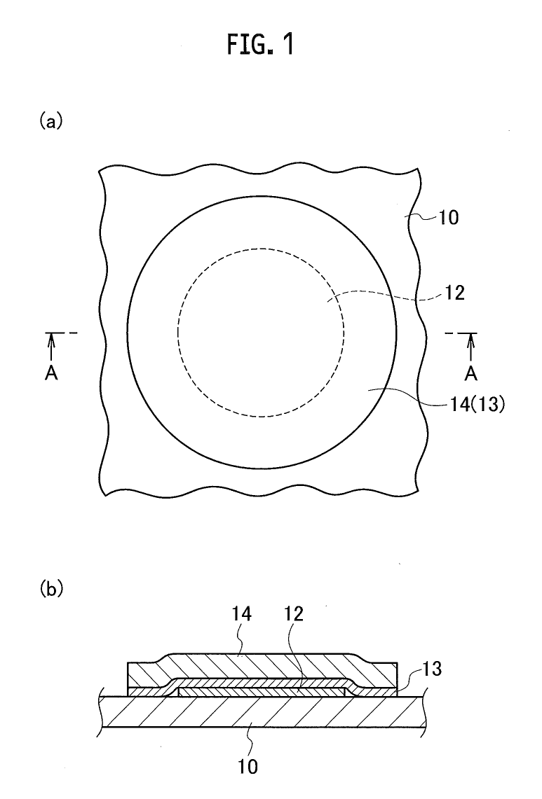

FIGS. 2(a) to 2(d) are schematic cross-sectional views illustrating the cutting process by expanding in accordance with a stealth dicing method.

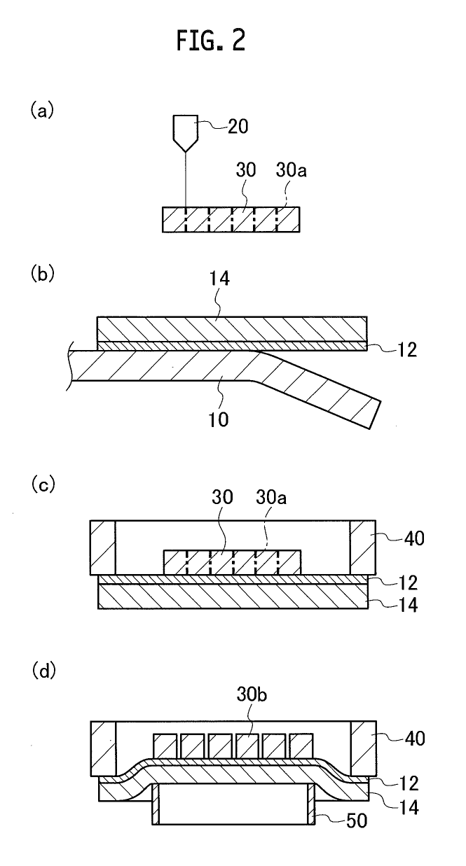

FIGS. 3(a) to 3(d) are schematic cross-sectional views illustrating the cutting process by expanding in accordance with a stealth dicing method.

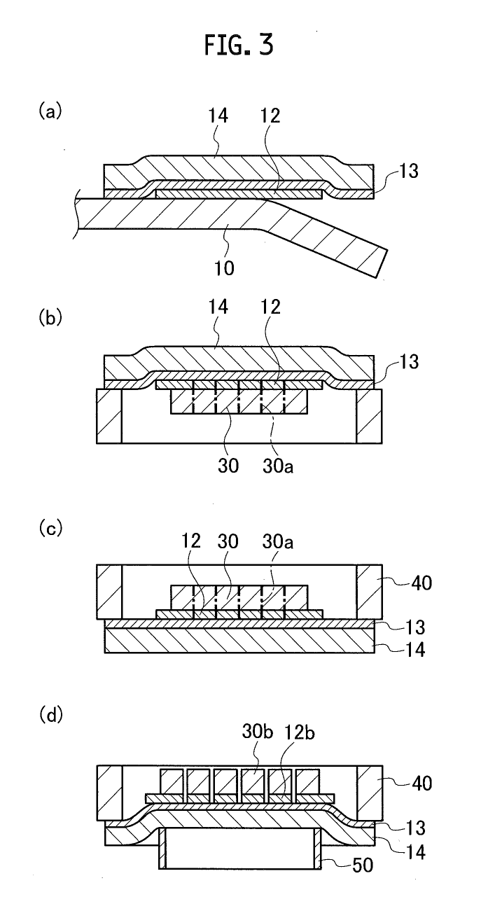

FIGS. 4(a) and 4(b) are schematic cross-sectional views illustrating the dispersion of DAF during the cutting process by expanding, and (a) shows a state before expanding and (b) shows a state after expanding.

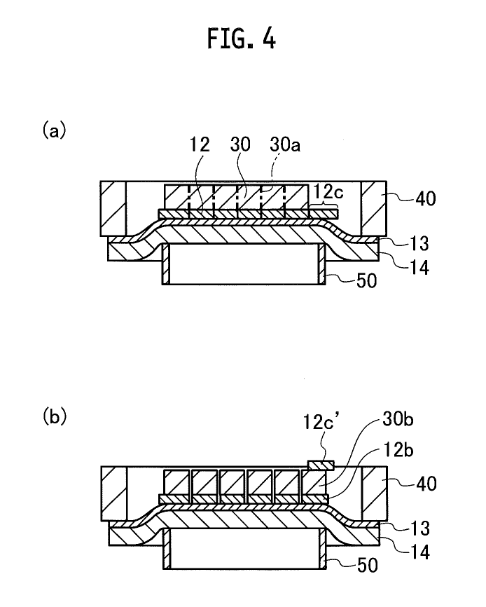

FIGS. 5(a) and 5(b) are views schematically showing an embodiment of the die bonding/dicing sheet of the present invention, and (a) is a plan view and (b) is a cross-sectional view taken along the B-B line in (a).

FIGS. 6(a) and 6(b) are views illustrating the structure of the die bonding/dicing sheet of the present invention, and (a) is a plan view and (b) is a cross-sectional view taken along the line C-C in (a).

### BEST MODE FOR CARRYING OUT THE INVENTION

The embodiments of the present invention will now be described in detail.

### (Die Bonding/Dicing Sheet)

The first aspect of the present invention relates to a die bonding/dicing sheet. The die bonding/dicing sheet is attached to a support member for mounting a semiconductor element cut by the dicing step in use. Herein, the above-mentioned “a support member for mounting a semiconductor element” constitutes a substrate for mounting a semiconductor element, and it means a member constituted of a material which can be diced when producing a semiconductor element. As an embodiment, the die bonding/dicing sheet includes a substrate for a silicon semiconductor element known as a semiconductor wafer, or a substrate for a semiconductor element constituted of other semiconductor materials.

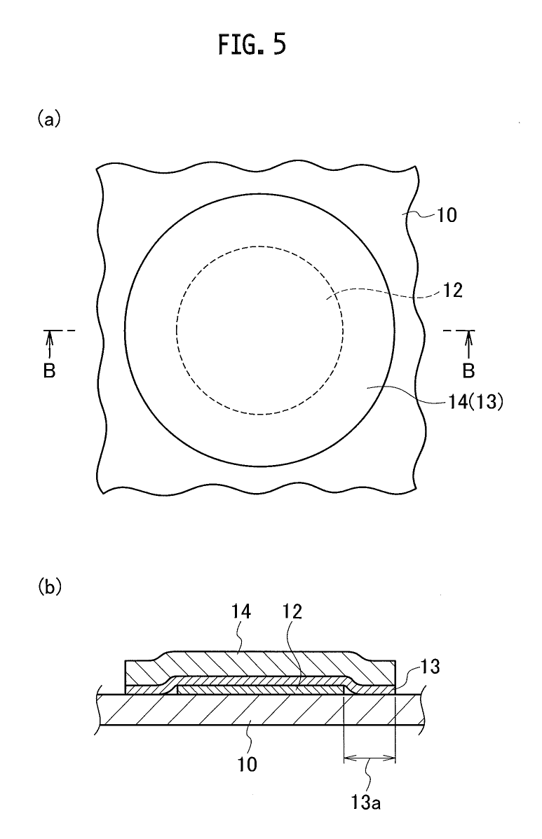

FIGS. 5(a) and 5(b) are views schematically showing an embodiment of the die bonding/dicing sheet of the present invention. As shown in FIGS. 5(a) and 5(b), the die bonding/dicing sheet of the present invention has a peelable first base material 10, an adhesive layer 12 provided on one surface of the first base material 10, a pressure sensitive adhesive layer 13 which covers the whole upper surface of the adhesive layer 12 and has a peripheral part 13a which does not overlap the adhesive layer 12, and a second base material 14 provided on the upper surface of the pressure sensitive adhesive layer 13.

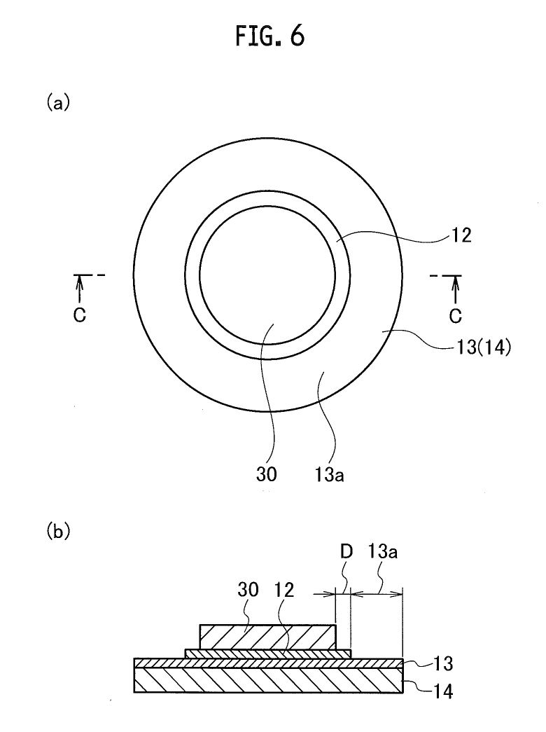

FIGS. 6(a) and 6(b) are views illustrating the structure of the die bonding/dicing sheet of the present invention. FIGS. 6(a) and 6(b) show a state in which the first base material 10 of the die bonding/dicing sheet of the present invention shown in FIGS. 5(a) and 5(b) is peeled off and then attached to a support member for mounting a semiconductor element (semiconductor wafer). As shown in detail in FIG. 6(b), the die bonding/dicing sheet of the present invention is characterized in that the plane outer shape of the adhesive layer 12 is larger than the plane outer shape of the support member 30 for mounting a semiconductor element, and the distance D between the edge of the adhesive layer 12 and the edge of the support member 30 is 1 mm or more and 12 mm or less.

Herein, the distance D is preferably 12 mm or less, more preferably 10 mm or less and further preferably 8 mm or less, from the viewpoint that the dispersion of an adhesive layer at the time of expanding is easily prevented. On the other hand, from the viewpoint of position gap in the step for laminating a semiconductor wafer and the above-mentioned sheet and device accuracy, the distance D is required to be at least 1 mm. In addition, it needs to adjust the position of the adhesive layer and the position of the pressure sensitive adhesive layer and the second base material when producing a die bonding/dicing sheet. In view of the above-mentioned position adjustment, the distance D is preferably 2 mm or more, and more preferably 3 mm or more. As described above, in consideration of both production aspects and device accuracy, the distance D is preferably in a range of 1 to 12 mm, more preferably a range of 2 to 10 mm, and further preferably a range of 3 to 8 mm as an embodiment.

As an embodiment, the die bonding/dicing sheet has a form in which the first base material is long in shape, and a plurality of laminates comprising the adhesive layer, the pressure sensitive adhesive layer and the second base material is arranged in the island-like form on an upper surface of the long-shaped first base material, and a side of the upper surface of the long-shaped first material is wound inward in long direction into a roll-like form.

The die bonding/dicing sheet of the present invention is only required to have the above-described predetermined form, and can be constituted using materials known in the art. The composition examples of each layer are not particularly limited and are as follows.

### (First Base Material)

As a peelable first base material, those well known as a protective film in the art can be used. In an embodiment, for example, a plastic film is preferably used. Specific examples of the plastic film includes a polyester-based film such as polyethylene terephthalate film, a polyolefin-based film such as polytetrafluoroethylene film, polyethylene film, polypropylene film, polymethylpentene film and polyvinyl acetate film, polyvinyl chloride film, polyimide film and the like. As another embodiment, paper, unwoven fabric, metallic foil and the like may be also used. Because the above-mentioned first base material is used for the protection of the sheet and peeled out when used, the surface to be peeled of the base material is preferably treated with a release agent such as a silicone-based stripper, a fluorine-based stripper or a long chain alkyl acrylate-based stripper in advance. In addition, the thickness of the first base material can be properly selected without losing working properties, and is commonly 1000 μm or less. As an embodiment, the thickness of the first base material is preferably 1 to 100 μm, more preferably 2 to 20 μm, and further preferably 3 to 10 μm.

### (Adhesive Layer)

An adhesive layer can be constituted with various known adhesive agents used for the adhesion (bonding) of a semiconductor chip. The adhesive agent is preferably one which can fix a semiconductor wafer at the time of dicing, function as a die bonding material after cutting the wafer, and easily bond the semiconductor chip to a substrate for mounting a chip. From such viewpoint, the adhesive agent is preferably adjusted so that the peel strength of the interface of the adhesive layer and a pressure sensitive adhesive layer before UV irradiation will be in an appropriate range. For example, at least one selected from the group consisting of a thermosetting adhesive agent, a photo-curable adhesive agent, a thermoplastic adhesive agent and an oxygen reactive adhesive agent may be used. The adhesive agent is not particularly limited and an adhesive agent comprising an epoxy resin, a phenol-based curing agent, an acrylic resin and an inorganic filler may be used. In an embodiment of the above-mentioned adhesive agent, the ratio of components is preferably in turn 10:5:5:8 in the weight ratio.

The adhesive layer may be formed by applying an adhesive agent on the above-mentioned first base material in accordance with a known method such as a coating method. The thickness of the adhesive layer is not particularly limited and is commonly desired to be in a range of 1 to 200 μm. When the thickness of an adhesion layer is 1 μm or more, sufficient die bonding adhesive strength is easily secured. On the other hand, when the thickness is above 200 μm, there are no advantages in characteristic aspects and it is uneconomical. From such viewpoint, the above-mentioned thickness is preferably 3 to 150 μm, and further preferably 10 to 100 μm as an embodiment.

### (Pressure Sensitive Adhesive Layer)

The pressure sensitive adhesive layer is not particularly limited and it may be constituted with a pressure sensitive adhesive known in the art. It is preferred that constituent components are appropriately adjusted so that a pressure sensitive adhesive can fix a semiconductor wafer and a second base material via an adhesive layer at the time of dicing but will be easily peeled off from the adhesive layer when picking up semiconductor chips obtained after cutting the wafer. As the pressure sensitive adhesive, for example, at least one selected from the group consisting of compounds having a diol group, isocyanate compounds, urethane (meth)acrylate compounds, diamine compounds, urea methacrylate compounds, and high energy ray-curable copolymers having an ethylenically unsaturated group in the side chain may be used. The pressure sensitive adhesive is preferably constituted with components which would not change easily viscosity with storage environments such as temperature, humidity, storage period, and the presence or absence of oxygen. More preferably, viscosity of the pressure sensitive adhesive would not change easily with the storage environments.

The pressure sensitive adhesive can also comprise a component which is curable by high-energy rays such as ultraviolet rays and radioactive rays and heating. Among such component, a component which is curable by the high-energy rays is preferred, and further a component which is curable by ultraviolet rays is particularly preferred. When a pressure sensitive adhesive comprises a component which is curable by high-energy rays such as ultraviolet rays and radioactive rays and heating, the adhesive power of the pressure sensitive adhesive can be also reduced by curing treatment.

### (Second Base Material)

A second base material can be a well-known base material which is used for a dicing sheet in the art. The base material is not particularly limited and various plastic films exemplified above as the first base material may be used. The above-mentioned base material may be a single layer structure or a multi-layer structure in which two or more of films are laminated. That is, in an embodiment, the base material is preferably constituted of at least one selected from the group consisting of: a polyester-based film such as a polyethylene terephthalate film; a polyolefin-based film such as a polytetrafluoroethylene film, a polyethylene film, a polypropylene film, a polymethylpentene film and a polyvinyl acetate film; a polyvinyl chloride film; and a polyimide film. It is preferred that a dicing sheet base material shows excellent expansibility at the time of expanding. From such viewpoint, in an embodiment, the polyolefin-based film is preferably used. The thickness of a dicing sheet base material is commonly in a range of 10 to 500 μm, and preferably 50 to 200 μm.

The above-mentioned die bonding/dicing sheet may be produced by a method well known in the art. The die bonding/dicing sheet may be produced, for example, by forming an adhesive layer and a pressure sensitive adhesive layer in turn on the first or second base material by a coating method. As another method, the sheet also may be produced by laminating an adhesion layer formed on the first base material and a pressure sensitive adhesive layer formed on the second base material each other.

The second aspect of the present invention relates to a method for producing a semiconductor device using the die bonding/dicing sheet of the present invention. The above-mentioned production method comprises: a step for attaching the adhesive layer of the die bonding/dicing sheet to the backside of a semiconductor wafer; a cutting step for dicing simultaneously the semiconductor wafer and the adhesive layer of the die bonding/dicing sheet; a step for picking up the diced semiconductor wafer (chip) with the adhesive layer and fixing it to a lead frame; a step for wire bonding; and a step for sealing. In the cutting step, a cutting method well known in the art can be applied, but a cutting method by expanding is preferred. Particularly, a method by expanding in accordance with a stealth dicing method is preferably applied.

A preferred embodiment of the present invention relates to relates to a method for producing a semiconductor device comprising a cutting process by expanding in accordance with a stealth dicing method, wherein the die bonding/dicing sheet of the first aspect of the present invention is used in the cutting process. According to such embodiment, the dispersion of DAF at the time of expanding can be inhibited, and thus a semiconductor chip can be obtained in a good yield, and an operation for picking up the semiconductor chip also can be carried out well. Therefore, a producing of semiconductor device can be efficiently performed.

In an embodiment of the method for producing the semiconductor device, the cutting process preferably comprises the steps:

(i) forming a modified part by irradiating a support member for mounting a semiconductor element with a laser,

(ii) laminating the support member for mounting the semiconductor element, and a die bonding/dicing sheet having in turn a peelable first base material, an adhesive layer, a pressure sensitive adhesive layer and a second base material, wherein the adhesion layer is exposed by peeling off the first base material of the die bonding/dicing sheet, and subsequently the adhesion layer and the support member for mounting the semiconductor element are laminated, and then

(iii) expanding the second base material and the pressure sensitive adhesive layer of the die bonding/dicing sheet to simultaneously cut the support member for mounting the semiconductor element and the adhesive layer, whereby obtaining individual pieces of the support member for mounting the semiconductor element with the adhesive layer.

Herein, the step (iii) is preferably performed under a condition of the expanding that the second base material and the pressure sensitive adhesive layer are not cut. A dicing sheet typically comprises a dicing sheet base material and a pressure sensitive adhesive layer provided thereon. In the step (iii), a dicing sheet (a second base material and a pressure sensitive adhesive layer) is stretched by applying an external force by expanding. The amount to stretch the dicing sheet is demanded to be greater because it becomes easy to cut a semiconductor wafer and an adhesive layer simultaneously. On the other hand, when the amount is too much, the dicing sheet itself is easily broken. The dicing sheet base material is not particularly limited and when a dicing sheet base material comprising an ionomer resin with a thickness of 100 μm is used, expanding is preferably performed under the conditions of a temperature of −15° C. to 0° C., an expanding velocity of 10 mm/sec, and an expanding amount of 10 to 15 mm. The expanding may be performed by using an expanding jig known in the art.

The method for producing a semiconductor device according to the present invention may comprise, if needed, (iv) a step for delivering active energy such as ultraviolet rays depending on the characteristics of the pressure sensitive adhesive layer in addition to the cutting process. When the pressure sensitive adhesive layer comprises a component which is curable by irradiation of active energy, adhesive strength between the adhesive layer and the pressure sensitive adhesive layer can be reduced by curing the pressure sensitive adhesive layer.

An embodiment of the method for producing a semiconductor device of the present invention further comprises other steps for producing a semiconductor device using a semiconductor chip obtained by the cutting process. Specifically, a semiconductor device may be produced by performing the cutting process comprising the steps (i) to (iv), followed by performing the following steps: (v) peeling off and picking up each semiconductor chip with the adhesive layer from the pressure sensitive adhesive layer, and putting this semiconductor chip with the adhesive layer on a support member such as a lead frame, and then performing heating and bonding; (vi) performing wire bonding; and (vii) sealing the semiconductor chip with a sealing material.

### EXAMPLES

The present invention will now be described in more detail by way of Examples and Comparative Examples thereof. It should be noted however that the present invention is not limited to the following examples.

### Example 1

A semiconductor wafer having a thickness of 100 μm and a diameter of 300 mm was prepared. A 10 mm×10 mm grid-like modified part was formed by irradiating the semiconductor wafer with a laser. In addition, a die bonding/dicing sheet with a diameter of 305 mm having an adhesive layer with a thickness of 60 μm, a pressure sensitive adhesive layer with a thickness of 20 μm and a second base material with a thickness of 150 μm was prepared on a peelable first base material. At this time, the peel strength of the interface between the adhesive and the pressure sensitive adhesive layer on a protective film before UV irradiation was adjusted to be 1.3 N/25 mm in a 90° peeling test method.

More specifically, a PET film was used as the first base material. The adhesive layer was formed by using a thermosetting material obtained by mixing an epoxy resin, a phenol-based curing agent, an acrylic resin and an inorganic filler in a weight ratio of 10:5:5:8. The pressure sensitive adhesion material layer was formed by using an acrylic resin comprising a UV-reactive component. An ionomer resin film was used as the second base material. The peel strength can be adjusted, for example, by changing the amount of UV-reactive component used.

The first base material of the die bonding/dicing sheet was peeled off to expose the adhesive layer. The adhesive layer surface of the die bonding/dicing sheet was attached to the wafer at 12 mm/sec and 70° C. And then, the cutting of the wafer was performed by expanding the wafer with the sheet, by lifting the dicing tape to 12 mm or above, at a velocity of 100 mm/sec under the condition of −15° C.

When cutting by expanding was performed and a lifting jig was returned to a place before lifting, the peeling of the adhesive layer in around the wafer and the adhesion of the adhesive layer to the upper surface of the wafer were evaluated in accordance with the following criteria. The results are shown in Table 1. The number of “A”, “B” and “C” in the table corresponds to the number of wafers evaluated.

(Evaluation Criteria)

A: An adhesive layer is not peeled off from a pressure sensitive adhesive layer. The adhesive layer is not also put on the upper surface of a wafer.

B: A part of an adhesive layer is peeled off from a pressure sensitive adhesive layer. However, the peeled adhesive layer has not reached the upper surface of a wafer.

C: An adhesive layer is peeled off from a pressure sensitive adhesive layer. Also, the peeled adhesive layer has reached the upper surface of a wafer (an adhesive layer is dispersed and adheres to the upper surface of a wafer).

### Example 2

A die bonding/dicing sheet was produced in the same manner as in Example 1 except that the external size of the adhesive layer in the die bonding/dicing sheet was changed to 312 mm in diameter. The obtained die bonding/dicing sheet was then used to cut a wafer in the same manner as in Example 1, and each evaluation was made. The results are shown in Table 1.

### Example 3

A die bonding/dicing sheet was produced in the same manner as in Example 1 except that the external size of the adhesive layer in the die bonding/dicing sheet was changed to 308 mm in diameter. The obtained die bonding/dicing sheet was then used to cut a wafer in the same manner as in Example 1, and each evaluation was made. The results are shown in Table 1.

### Example 4

A die bonding/dicing sheet was produced in the same manner as in Example 1 except that the external size of the adhesive layer in the die bonding/dicing sheet was changed to 303 mm in diameter. The obtained die bonding/dicing sheet was then used to cut a wafer in the same manner as in Example 1, and each evaluation was made. The results are shown in Table 1.

### Comparative Example 1

A die bonding/dicing sheet was produced in the same manner as in Example 1 except that the external size of the adhesive layer in the die bonding/dicing sheet was changed to 320 mm in diameter. The obtained die bonding/dicing sheet was then used to cut a wafer in the same manner as in Example 1, and each evaluation was made. The results are shown in Table 1.

TABLE 1

| | DIAMETER OF | | |
|---|---|---|---|
| | ADHESIVE | | EVALUATION |
| | LAYER | | RESULTS |
| EXAMPLE 1 | 305 | mm | AABAAB |
| EXAMPLE 2 | 312 | mm | BBBBBB |
| EXAMPLE 3 | 308 | mm | ABABAB |
| EXAMPLE 4 | 303 | mm | AAAAAA |
| COMPARATIVE | 320 | mm | CCCCCC |
| EXAMPLE 1 | | | |

### REFERENCE SIGNS LIST

10: Peelable first base material (Peelable sheet, Protective film)
12: Adhesive layer, 12b: Cut adhesive layer, 12c: Part of adhesive layer out of contact with semiconductor wafer, and 12c′: Dispersed and adhering adhesive layer
13: Pressure sensitive adhesive layer, 13a: Peripheral part
14: Second base material (dicing sheet base material)
20: Laser source
30: Support member (Semiconductor wafer), 30a: Modified part by laser, and 30b: Semiconductor chip
40: Dicing ring
50: Expanding and cutting jig
D: Distance between edge of adhesive layer and edge of pressure sensitive adhesive layer

1. A die bonding/dicing sheet, which is attached to a support member for mounting a semiconductor element in use, comprising:
a first base material which is peelable;
an adhesive layer provided on one surface of the first base material;
a pressure sensitive adhesive layer, which covers a whole upper surface of the adhesive layer and has a peripheral part which does not overlap the adhesive layer; and
a second base material provided on an upper surface of the pressure sensitive adhesive layer,
wherein a plane outer shape of the adhesive layer is larger than a plane outer shape of the support member for mounting the semiconductor element, and a distance between an edge of the adhesive layer and an edge of the support member is 1 mm or more and 12 mm or less.

2. The die bonding/dicing sheet according to claim 1, wherein the support member for mounting the semiconductor element is a semiconductor wafer.

3. The die bonding/dicing sheet according to claim 1, wherein the first base material is long in shape, and a plurality of laminates comprising the adhesive layer, the pressure sensitive adhesive layer and the second base material is arranged in an island-like form on an upper surface of the long-shaped first base material, and a side of the upper surface of the long-shaped first material is wound inward in long direction into a roll-like form.

4. The die bonding/dicing sheet according to claim 1, wherein the second base material is a dicing sheet base material which is not broken when cut by expanding is performed in accordance with a stealth dicing method.

5. A method for producing a semiconductor device, comprising a cutting process by expanding performed in accordance with a stealth dicing method,
wherein the cutting process including the steps:
(i) forming a modified part by irradiating a support member for mounting a semiconductor element with a laser;
(ii) laminating the support member for mounting the semiconductor element, and a die bonding/dicing sheet having in turn a peelable first base material, an adhesive layer, a pressure sensitive adhesive layer and a second base material, wherein the adhesive layer is exposed by peeling off the first base material of the die bonding/dicing sheet, and subsequently the adhesive layer and the support member for mounting the semiconductor element are laminated; and then
(iii) expanding the second base material and the pressure sensitive adhesive layer of the die bonding/dicing sheet to simultaneously cut the support member for mounting the semiconductor element and the adhesive layer, whereby obtaining individual pieces of the support member for mounting the semiconductor element with the adhesive layer, and
wherein as the die bonding/dicing sheet in the cutting process, the die bonding/dicing sheet according to claim 1 is used.

6. The method for producing a semiconductor device according to claim 5, wherein the step (iii) is performed under a condition of the expanding that the second base material and the pressure sensitive adhesive layer are not cut.
